(19) United States
(12) Patent Application Publication
(10) Pub. No.: US 2026/0191101 A1
(43) Pub. Date: Jul. 2, 2026

(54) PROCESSOR PACKAGE INTEGRATED WITH OPTICAL ENGINE AND METHOD OF MANUFACTURING THE SAME

(71) Applicant: SAMSUNG ELECTRONICS CO., LTD., Suwon-si (KR)

(72) Inventors: Heejin CHOI, Suwon-si (KR); Woosung KIM, Suwon-si (KR); Geundo PARK, Suwon-si (KR); Nakyeong EOM, Suwon-si (KR); Junghua CHANG, Suwon-si (KR)

(73) Assignee: SAMSUNG ELECTRONICS CO., LTD., Suwon-si (KR)

(21) Appl. No.: 19/240,800

(22) Filed: Jun. 17, 2025

(30) Foreign Application Priority Data
Dec. 31, 2024 (KR) 10-2024-0202733

(51) Int. Cl. H01L 25/16; G02B 6/42; H01L 21/56; H01L 23/00; H01L 23/31; H10B 80/00; H10D 80/30

(52) U.S. Cl. CPC H10W 90/00; G02B 6/4206; G02B 6/4239; G02B 6/4244; G02B 6/4245; G02B 6/4249; H10B 80/00; H10D 80/30; H10W 74/016; H10W 74/114; H10W 72/877; H10W 90/724; H10W 90/732

(57) ABSTRACT

A processor package includes an interposer; a memory on the interposer; a processor on the interposer; and an optical engine on the interposer, wherein the optical engine includes: a photonic integrated circuit chip including circuit elements, the circuit elements configured to perform photoelectric conversion, and a coupling structure on the photonic integrated circuit chip, the coupling structure configured to provide at least one of an optical input path or an optical output path, wherein the at least one of the optical input path or the optical output path is connected to the photonic integrated circuit chip, and wherein the coupling structure includes: a plurality of light output patterns including a dummy pattern and an effective pattern, and a mold layer on the dummy pattern.

### CROSS-REFERENCE TO RELATED APPLICATION

This application is based on and claims priority under 35 U.S.C. § 119 to Korean Patent Application No. 10-2024-0202733, filed on Dec. 31, 2024, in the Korean Intellectual Property Office, the disclosure of which is incorporated by reference herein in its entirety.

### BACKGROUND

### 1. Field

The disclosure relates to a processor package and a method of manufacturing the same.

### 2. Description of Related Art

Silicon photonics co-packaged optics (CPO) is considered as a way to implement ultra-high bandwidth and low-power consumption interconnect for artificial intelligence (AI) systems.

To integrate CPO with host integrated circuits (IC) such as graphical processing units (GPU), central processing units (CPU), and field programmable gate arrays (FPGA), a substrate packaging method may be used. This substrate packaging method is a method of transmitting serialized signals from the host IC to an optical engine through an organic substrate. The input/output (I/O) density of the organic substrate may be approximately 100/mm², and the transmission loss may be 0.2 dB/mm/GHz. The minimum spacing between chips may be around 1.5 mm and about 20 GHz signals may be transmitted. This is approximately equivalent to a 6 dB loss. In other words, CPO may be implemented through-6 dB channel packaging to transmit from the host IC to the optical engine in a substructure packaging method. Since this method receives input in the form of a serialized signal, the channel loss increases in proportion to the frequency as the interconnect speed increases. Accordingly, there is a need for a structure capable of efficient signal transmission between the host IC and the optical engine.

### SUMMARY

Provided are a processor package with which an optical engine is integrated and a method of manufacturing the same may be provided.

According to an aspect of the disclosure, a processor package may include an interposer; a memory on the interposer; a processor on the interposer; and an optical engine on the interposer, wherein the optical engine includes: a photonic integrated circuit chip including circuit elements, the circuit elements configured to perform photoelectric conversion, and a coupling structure on the photonic integrated circuit chip, the coupling structure configured to provide at least one of an optical input path or an optical output path, wherein the at least one of the optical input path or the optical output path is connected to the photonic integrated circuit chip, wherein the coupling structure may include: a plurality of light output patterns including a dummy pattern and an effective pattern, and a mold layer on the dummy pattern, wherein the effective pattern is configured to receive light from an outside of the optical engine.

The optical engine may further include an electronic integrated circuit chip on the photonic integrated circuit chip, the electronic integrated circuit chip configured to drive the circuit elements.

The coupling structure may further include a light-transmitting block on the photonic integrated circuit chip, wherein the plurality of light output patterns are on one surface of the light-transmitting block.

The coupling structure may further include a frame on the light-transmitting block, wherein the frame horizontally surrounds the effective pattern, and an upper portion of the effective pattern is exposed from the frame.

The frame may include a shape that surrounds the dummy pattern and the effective pattern, wherein a portion of the shape is between the dummy pattern and the effective pattern.

The processor package may further include a mold material on the interposer, in spaces between the memory, the processor, and the optical engine, wherein a material of the mold material is the same as a material of the mold layer.

The semiconductor package may further include a fiber array unit on the coupling structure and optically connected to the effective pattern.

The photonic integrated circuit chip and the coupling structure may include: a dummy channel region including the dummy pattern; and a functional channel region including the effective pattern.

The photonic integrated circuit chip may further include a coupling device that is configured to change an optical path in a direction toward the plurality of light output patterns.

The interposer may include a silicon interposer or a redistribution layer (RDL) interposer.

According to an aspect of the disclosure, an electronic device may include: a processor package; an input interface configured to be electrically connected to the processor package; and an output interface configured to be electrically connected to the processor package, wherein the processor package may include: an interposer, a memory on the interposer, a processor on the interposer, and an optical engine on the interposer, wherein the optical engine may include: a photonic integrated circuit chip including circuit elements, the circuit elements configured to perform photoelectric conversion, and a coupling structure on the photonic integrated circuit chip, the coupling structure configured to provide at least one of an optical input path or an optical output path, wherein the at least one of the optical input path or the optical output path is connected to the photonic integrated circuit chip, wherein the coupling structure may include: a plurality of light output patterns including a dummy pattern and an effective pattern, and a mold layer on the dummy pattern, and wherein the effective pattern is configured to receive light from an outside of the optical engine.

According to an aspect of the disclosure, a method of manufacturing processor package may include: forming an optical engine by arranging, on a photonic integrated circuit chip, a coupling structure and an electronic integrated circuit chip, wherein the coupling structure includes a plurality of light output patterns including a dummy pattern and an effective pattern, and the photonic integrated circuit chip includes circuit elements, the circuit elements configured to perform photoelectric conversion, and the electronic integrated circuit chip configured to drive the circuit elements; forming a mold layer on the dummy pattern; and arranging the optical engine on an interposer, wherein, after the forming the mold layer, the effective pattern is configured to receive light from an outside of the optical engine.

The coupling structure may include: a light-transmitting block, wherein the plurality of light output patterns are on one surface of the light-transmitting block; and a frame on the light-transmitting block and surrounding an upper portion of the effective pattern and a periphery of the effective pattern.

The frame may include a shape that horizontally surrounds the dummy pattern and the effective pattern, wherein a portion of the shape is between the dummy pattern and the effective pattern, and wherein the frame includes a first space above the dummy pattern and a second space above the effective pattern, wherein a height of the first space is greater than a height of the second space.

According to an aspect of the disclosure, the method may further include etching, before the forming the mold layer, an upper portion of the frame so that the dummy pattern is exposed from the frame and the effective pattern is not exposed from the frame.

The frame may include an upper portion that is above the upper portion of the effective pattern, with a space between the upper portion of the frame and the upper portion of the effective pattern, and the dummy pattern is exposed from the frame.

The forming the mold layer on the dummy pattern may include providing a mold material in a region between the electronic integrated circuit chip and the coupling structure, wherein the mold material is the same as a material of the mold layer.

The method may further include exposing, after the forming the mold layer, the effective pattern by etching the upper portion of the frame.

The method may further include arranging a fiber array unit on the frame, the fiber array unit configured to optically connect the effective pattern.

The interposer may be a silicon interposer or a redistribution layer (RDL) interposer.

Additional aspects of the disclosure will be set forth in part in the description which follows and, in part, will be apparent from the description, or may be learned by practice of the presented example embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view showing a schematic configuration of a processor package according to an embodiment;

FIG. 2 is a cross-sectional view illustrating a structure in which a coupling structure is arranged on a photonic integrated circuit in an optical engine of a processor package according to an embodiment;

FIG. 3 is a cross-sectional view illustrating a structure in which a coupling structure is arranged on a photonic integrated circuit in an optical engine of a processor package according to an embodiment;

FIG. 4 is a cross-sectional view showing a schematic configuration of a processor package according to an embodiment;

FIG. 5 is a cross-sectional view showing a schematic configuration of a processor package according to an embodiment;

FIG. 6 is a cross-sectional view showing a schematic configuration of a processor package according to an embodiment;

FIG. 7 is a cross-sectional view showing a schematic configuration of a processor package according to an embodiment;

FIG. 8 is a cross-sectional view showing a schematic configuration of a processor package according to an embodiment;

FIG. 9 is a cross-sectional view showing a schematic configuration of a processor package according to an embodiment;

FIGS. 10A to 10J are diagrams for describing a method of manufacturing a processor package, according to an embodiment;

FIGS. 11A to 11H are diagrams for describing a method of manufacturing a processor package, according to an embodiment; and

FIG. 12 is a block diagram schematically illustrating an electronic device according to an embodiment.

### DETAILED DESCRIPTION

Reference will now be made in detail to non-limiting example embodiments of the disclosure, with reference to the accompanying drawings, wherein like reference numerals refer to like elements throughout. In this regard, embodiments of the disclosure may have different forms and should not be construed as being limited to the descriptions set forth herein. Accordingly, the example embodiments are merely described below, by referring to the figures, to explain example aspects of the disclosure. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, or c,” should be understood as including only a, only b, only c, both a and b, both a and c, both b and c, or all of a, b, and c.

Embodiments described below are merely illustrative, and various modifications are possible from these embodiments. In the drawings, the same reference numerals refer to the same components, and the size of each component in the drawings may be exaggerated for clarity and convenience of description.

Hereinafter, the term “upper portion” or “on” may also include “to be present above on a non-contact basis” as well as “to be on the top portion in directly contact with.”

Terms such as “first” and “second” may be used to describe various components, but are used only for the purpose of distinguishing one component from another. These terms do not limit the difference in the material or structure of the components.

Singular expressions include plural expressions unless the context clearly means otherwise. In addition, when a part “contains” (or “includes” or “comprises”) a component, this means that it may contain (or include or comprise) other components, rather than excluding other components, unless otherwise stated.

Further, the terms “unit”, “module,” or the like mean a unit that processes at least one function or operation, which may be implemented in hardware or software or implemented in a combination of hardware and software.

The use of the term “the” and similar indicative terms may correspond to both singular and plural.

The operations constituting a method of the disclosure may be performed in various appropriate orders unless there is an explicit mention that the operations should be performed in the order described. In addition, the use of all illustrative terms (e.g., etc.) is simply intended to detail example aspects of the disclosure and, unless explicitly limited by the disclosure, the scope of disclosure is not limited due to the terms.

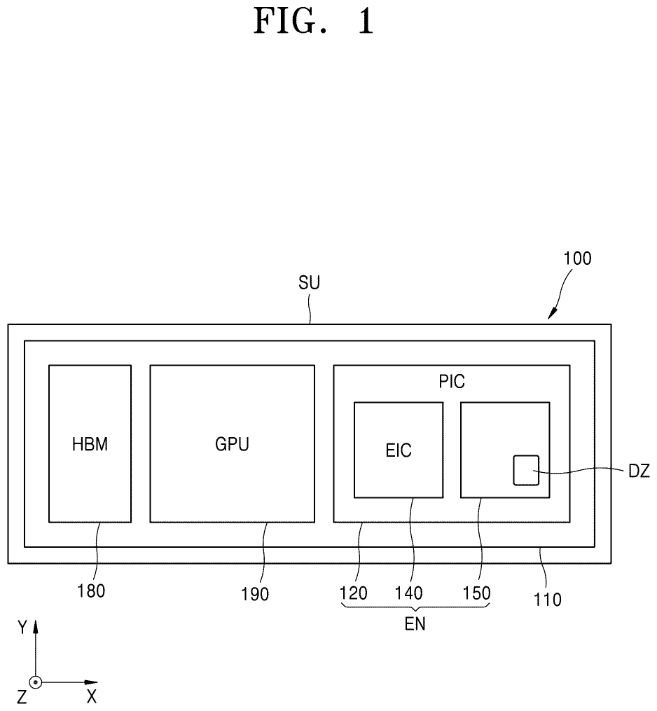

FIG. 1 is a plan view showing a schematic configuration of a processor package according to an embodiment.

A processor package 100 according to an embodiment may have a structure in which an optical engine EN is packaged together with a host IC.

The processor package 100 may include an interposer 110, and a memory 180, a processor 190, and the optical engine EN, which may be arranged on the interposer 110. The interposer 110 may be arranged on a substrate SU. The substrate SU may be a package substrate such as, for example, a printed circuit board (PCB).

The interposer 110 may be a microcircuit board used to integrate semiconductor chips manufactured in different processes such as, for example, a memory 180 and a logic device into one package. By the interposer 110, a difference in wiring width (pitch) between the integrated circuit IC chip and the substrate SU (e.g., a PCB) may be buffered. In other words, the wiring width of the circuit included in the interposer 110 may be a value between the wiring width of the integrated circuit chip and the wiring width of the substrate SU (e.g., the PCB). The interposer 110 may be a silicon interposer or a redistribution layer (RDL) interposer.

The memory 180 may be a high bandwidth memory (HBM), but is not limited thereto.

The processor 190 may be a GPU, or may include a CPU or a FPGA, but is not limited thereto.

The optical engine EN may include circuit elements configured to perform photoelectric conversion. The optical engine EN may convert an electrical signal into an optical signal or convert an optical signal into an electrical signal, at one end of an optical interconnect, and may also provide a transmission path of light input and output to and from optical communication.

The optical engine EN may include a photonic integrated circuit (PIC) chip 120, including the circuit elements configured to perform photoelectric conversion, and a coupling structure 150 arranged on the PIC chip 120 and configured to provide an optical input/output path. The optical input/output path may be connected to the PIC chip 120. The optical engine EN may also further include an electronic integrated circuit (EIC) chip 140 arranged on the PIC 120, and the EIC chip 140 may be configured to drive photoelectric conversion circuit elements (e.g., the circuit elements of the PIC chip 120).

A plurality of light output patterns may be provided on the top surface of the coupling structure 150, and some of the plurality of light output patterns may be included in a dummy channel region DZ. The light output pattern included in the dummy channel region DZ may be referred to as a dummy pattern. The dummy channel region DZ may be provided to perform an optical test during a process of manufacturing the processor package 100. In other words, the dummy channel region DZ may be provided to test the optical performance of the optical engine EN and determine the good/bad quality of the optical engine EN before the optical engine EN is packaged with the processor 190. The dummy channel region DZ may be a region extending from an upper portion of the coupling structure 150 to a predetermined region in the PIC 120. The light output pattern, which is a dummy pattern, that is, the dummy pattern arranged in the dummy channel region DZ, may be exposed before the good/bad quality test, and may be covered with a mold layer after being packaged on the interposer 110. The dummy channel region DZ shown in FIG. 1 is an example, and the location, size, and shape shown in FIG. 1 do not limit the dummy channel region DZ.

According to embodiments of the disclosure, a structure may be provided that ensures inter-process test result consistency of the optical engine EN performance in consideration of a molding process involved for electrical isolation and stress relief when the optical engine EN is packaged with the processor 190. Molding materials may have low light transmittance, and thus, for optical testing, some manufactured packages of comparative embodiments are sampled and then optically tested after the molding is removed. This process of comparative embodiments is uneconomical in terms of time and cost, and, in the comparative embodiments, it is difficult to secure the inter-process test result consistency because it is difficult to increase the number of samples.

Since the optical engine EN structure of an embodiment of the disclosure may be tested for discrimination of good/bad quality before the optical engine EN is packaged together with the processor 190, the number of test samples may be efficiently increased, and the inter-process test result consistency may be further increased.

The optical engine EN may receive an optical signal in the processor package 100, convert the optical signal into an electrical signal, and transmit the electrical signal to the processor 190. The optical engine EN may also convert an electrical signal from the processor 190 into an optical signal, and transmit the optical signal to the outside. The signal transmission between the optical engine EN and the processor 190 may be performed through the interposer 110, thereby minimizing transmission loss. For example, compared to the case where the optical engine EN is not directly arranged on the interposer 110 and is connected to the host IC through a PCB, transmission loss may be significantly reduced.

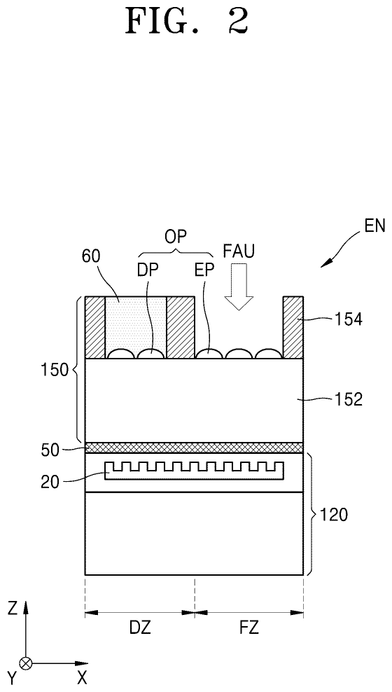

FIG. 2 is a cross-sectional view illustrating a structure in which the coupling structure 150 is arranged on the PIC chip 120 in the optical engine EN of the processor package 100 of FIG. 1.

FIG. 2 shows an arrangement relationship between the PIC chip 120 and the coupling structure 150 of the optical engine EN, and the illustration of the EIC chip 140 is omitted.

The coupling structure 150 may include a plurality of light output patterns OP including a dummy pattern DP and an effective pattern EP. Although the light output pattern OP is illustrated in a lens shape, the light output pattern OP is not limited thereto, and may be modified into any shape capable of outputting light. There may be one or more dummy patterns DP, and there may be a plurality of effective patterns EP. A plurality of light output patterns OP may be formed on the top surface of a light-transmitting block 152 of the coupling structure 150. The light-transmitting block 152 may include a glass material or a transparent plastic material. The coupling structure 150 may further include a frame 154 surrounding the effective pattern EP. The frame 154 may be arranged on the light-transmitting block 152. As shown, the frame 154 may have a shape surrounding a plurality of effective patterns EP and a plurality of dummy patterns DP, and by distinguishing the plurality of effective patterns EP from the plurality of dummy patterns DP. For example, a portion of the frame 154 may be between the plurality of effective patterns EP and the plurality of dummy patterns DP. The frame 154 may surround a side portion of the plurality of effective patterns EP and side portions of the plurality of dummy patterns DP, and an upper portion of the plurality of effective patterns EP and an upper portion of the plurality of dummy patterns DP may be exposed. The upper portion of the dummy patterns DP may be covered with a mold layer 60, and light from a fiber array unit FAU may enter only the effective patterns EP. For example, the light from the fiber array unit FAU may not enter the dummy patterns DP due to the mold layer 60. For example, the mold layer 160 may be configured to block the dummy patterns DP from receiving the light.

The PIC chip 120 may include a photoelectric conversion device, an optical waveguide, an electrical wiring, an optical coupler, and the like. The PIC chip 120 may include a coupling device 20 at one end of the PIC chip 120. The coupling device 20 may be an optical device arranged at a position facing the plurality of light output patterns OP to change a path of light traveling in the PIC chip 120 in a direction (e.g., Z direction) toward the plurality of light output patterns OP. The coupling device 20 may also change a path of light incident through the light output pattern OP so as to proceed within the PIC chip 120. The coupling device 20 may be referred to as a vertical emitter. The coupling device 20 may be a grating coupler. The PIC chip 120 may include various circuit elements, which are not shown in FIG. 2 for convenience of illustration. Additionally, the illustration of the optical engine EN in FIG. 2 is a non-limiting example, and embodiments of the disclosure are not limited to the illustrated form.

The PIC chip 120 and the coupling structure 150 may define a dummy channel region DZ and a function channel region FZ. The dummy channel region DZ may be a region corresponding to the dummy pattern DP, and the function channel region FZ may be a region corresponding to the effective pattern EP. For example, the dummy pattern DP may be in the dummy channel region DZ, and the effective pattern EP may be in the function channel region FZ. The dummy channel region DZ may be a region used in an optical test process, that is, the optical performance of the optical engine EN may be tested using light incident through the dummy pattern DP. After the optical test, the mold layer 60 may be formed above the dummy pattern DP, and light from the fiber array unit FAU may not be incident on the dummy pattern DP. That is, the dummy channel region DZ may be a region that does not form an optical path when the processor package 100 is operated after manufactured. During the operation of the processor package 100 that has been manufactured, light from the fiber array unit FAU may enter the function channel region FZ through the effective pattern EP. The region division of the dummy channel region DZ and the function channel region FZ shown in the diagram indicates that the regions in which the paths of light incident through the dummy pattern DP and the effective pattern EP are formed are provided in the PIC chip 120, respectively, and the region division of embodiments of disclosure is not limited to the region division shown.

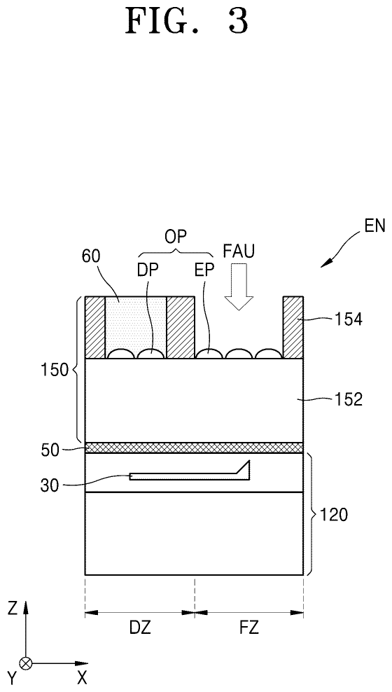

FIG. 3 is a cross-sectional view illustrating a structure in which a coupling structure is arranged on the photonic integrated circuit in the optical engine EN of the processor package 100 of FIG. 1.

A coupling device 30 provided in the PIC chip 120 is different from the coupling device 20 provided in the PIC chip 120 of FIG. 2 in that the coupling device 30 may be an edge coupler. The illustrated structure is an example and is not limited to the illustrated form.

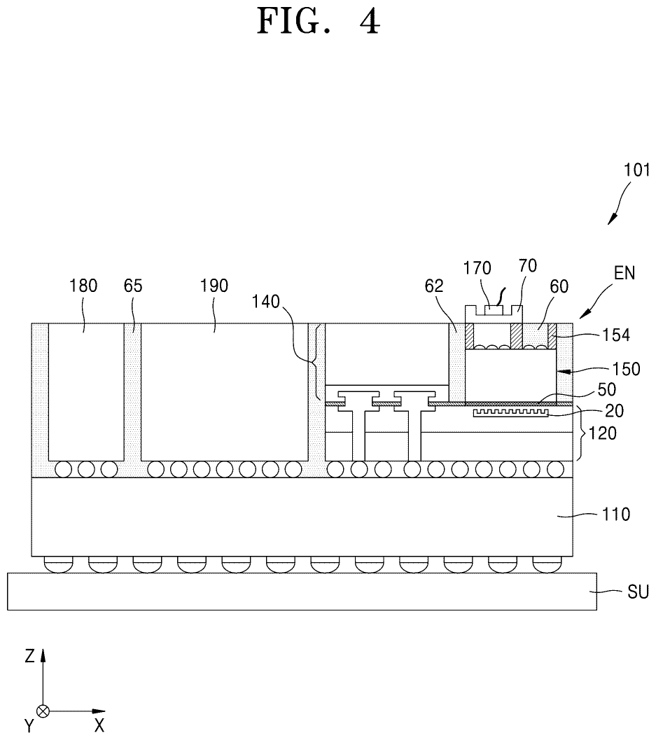

FIG. 4 is a cross-sectional view showing a schematic configuration of a processor package according to an embodiment.

A processor package 101 may include an interposer 110, a memory 180, a processor 190, and an optical engine EN. The optical engine EN may include a PIC chip 120, an EIC chip 140, and a coupling structure 150.

The memory 180, the processor 190, and the optical engine EN may be electrically connected to each other by the interposer 110. A through silicon via electrode or an RDL may be provided in the interposer 110. The interposer 110 may be a silicon interposer or an RDL interposer.

A region between (e.g., in an X direction) the EIC chip 140 and the coupling structure 150 may be filled with a mold material 62, and the mold material 62 may be the same material as a material of the mold layer 60 covering the dummy pattern DP. However, embodiments of the disclosure are not limited thereto. A region between (e.g., in the X direction) the memory 180, the processor 190, and the optical engine EN may also be filled with a mold material 65, and the mold material 65 may include the same material as the material of the mold layer 60 covering the dummy pattern DP. However, embodiments of the disclosure are not limited thereto.

A fiber array unit 170 may be arranged to face the effective pattern EP so that light may be input and output to and from the PIC chip 120 through the effective pattern EP. The fiber array unit 170 may be arranged to be seated on a receptacle 70 arranged on a frame 154.

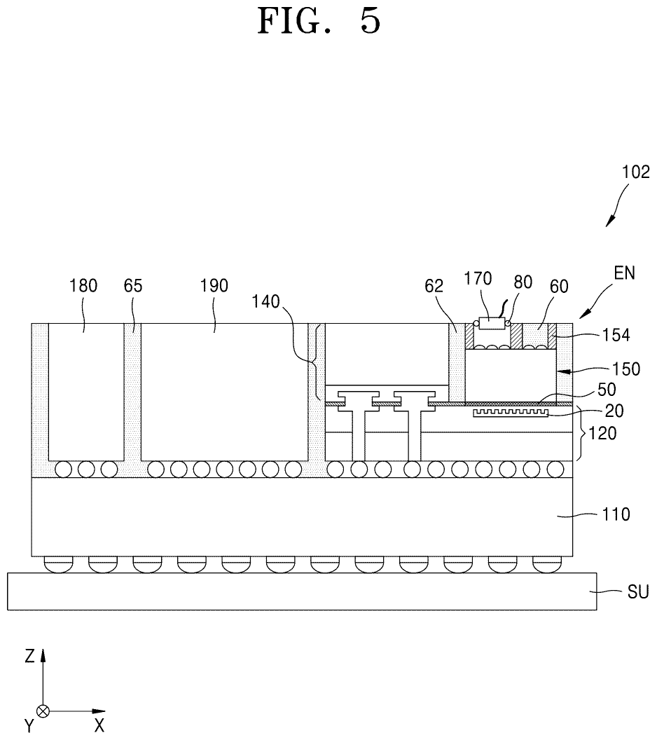

FIG. 5 is a cross-sectional view showing a schematic configuration of a processor package according to an embodiment.

A processor package 102 of the present embodiment may be substantially the same as or similar to the processor package 101 of FIG. 4, except that the fiber array unit 170 may be coupled to the frame 154 through a latch 80.

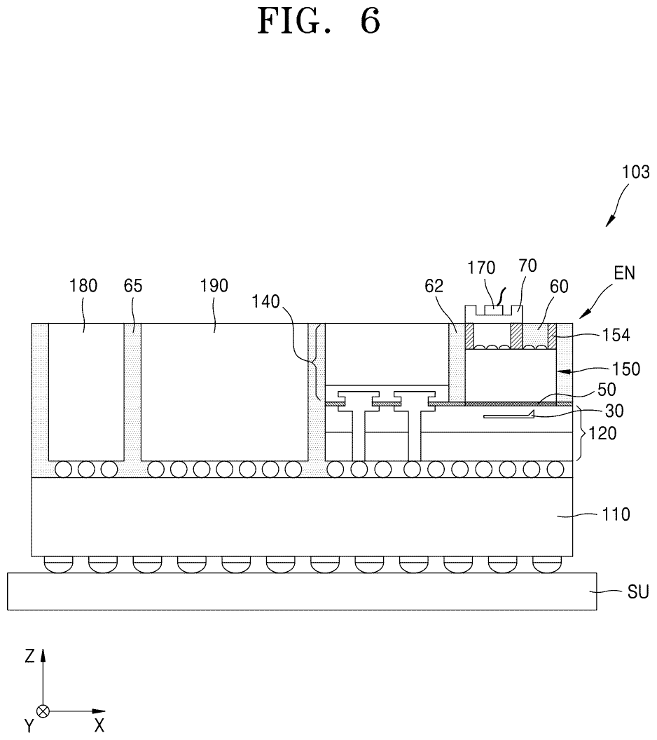

FIG. 6 is a cross-sectional view showing a schematic configuration of a processor package according to an embodiment.

A processor package 103 of the present embodiment may be substantially the same as or similar to the processor package 101 of FIG. 4, except that the coupling device 30 provided in the PIC chip 120 may be an edge coupler.

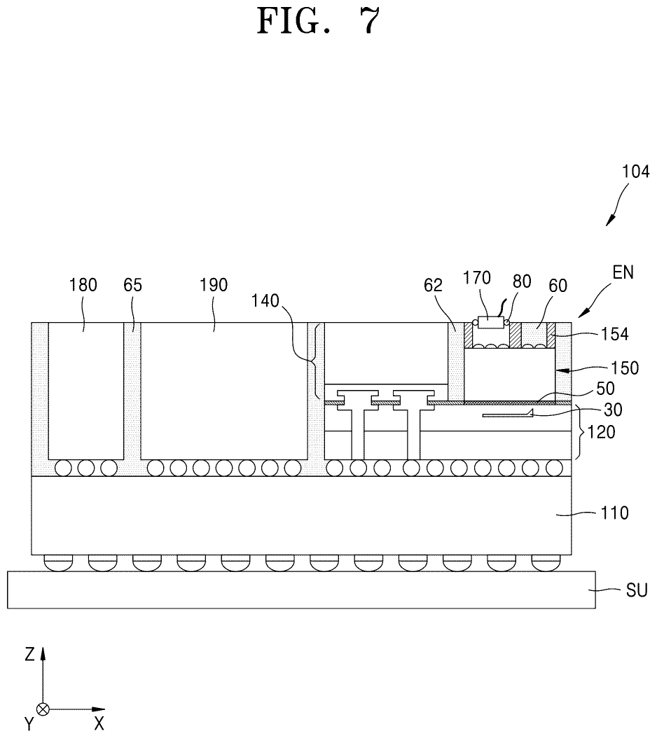

FIG. 7 is a cross-sectional view showing a schematic configuration of a processor package according to an embodiment.

A processor package 104 of the present embodiment may be substantially the same as or similar to the processor package 102 of FIG. 5, except that the coupling device 30 provided in the PIC chip 120 may be an edge coupler.

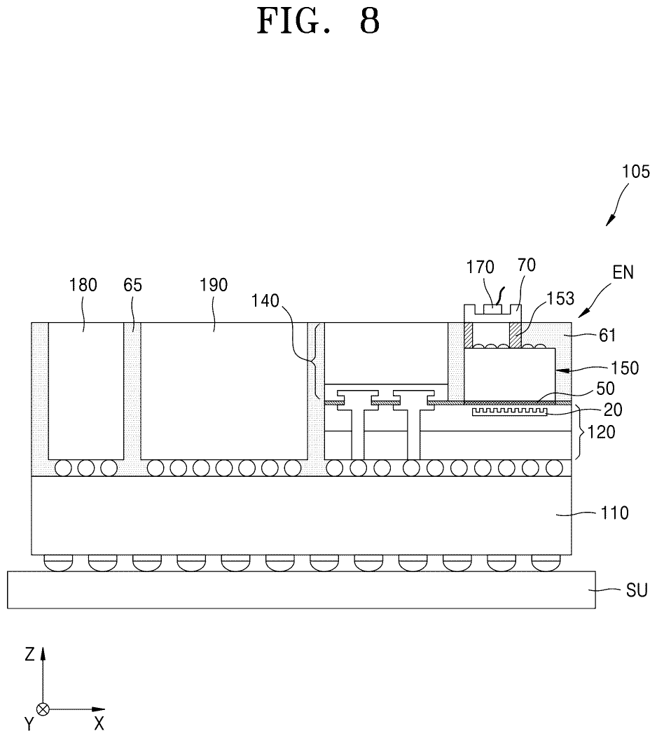

FIG. 8 is a cross-sectional view showing a schematic configuration of a processor package according to an embodiment.

Unlike the frame 154 provided in the processor packages 101, 102, 103, and 104 described above, a frame 153 provided in a processor package 105 according to the present embodiment has a shape surrounding only the effective pattern EP, and does not separately surround the dummy pattern DP. A mold layer 61 covering the dummy pattern DP may include a region between (e.g., in the X direction) the EIC chip 140 and the coupling structure 150 to extend to the entire region on the PIC chip 120.

A form in which the fiber array unit 170 is coupled to the frame 153 is illustrated in the structure illustrated in FIG. 4, but may be changed to a form as shown in FIG. 5.

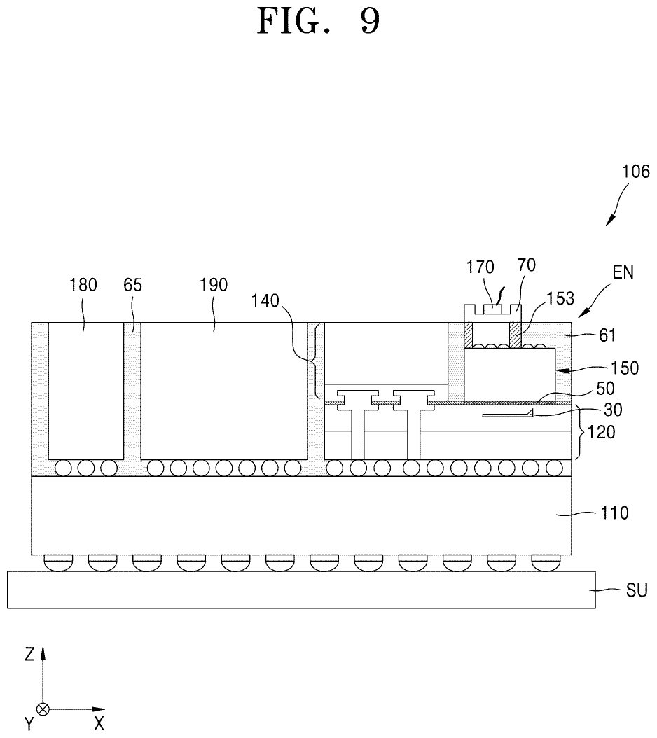

FIG. 9 is a cross-sectional view showing a schematic configuration of a processor package according to an embodiment.

A processor package 106 of the present embodiment may be substantially the same as or similar to the processor package 105 of FIG. 8, except that the coupling device 30 provided in the PIC chip 120 may be an edge coupler.

A form in which the fiber array unit 170 is coupled to the frame 153 is illustrated in the structure illustrated in FIG. 4, but may be changed to a form as shown in FIG. 5.

A method of manufacturing a processor package may include: preparing a coupling structure including a plurality of light output patterns including a dummy pattern and an effective pattern; forming an optical engine by arranging the coupling structure and an electronic integrated circuit chip on a photonic integrated circuit chip, wherein the photonic integrated circuit chip includes circuit elements for photoelectric conversion and the electronic integrated circuit chip drives the circuit elements; forming a mold layer on the dummy pattern; and arranging the optical engine on an interposer.

According to this manufacturing method, the processor packages 100, 101, 102, 103, 104, 105 and 106 of the embodiments described above may be manufactured, and detailed operations will be described below.

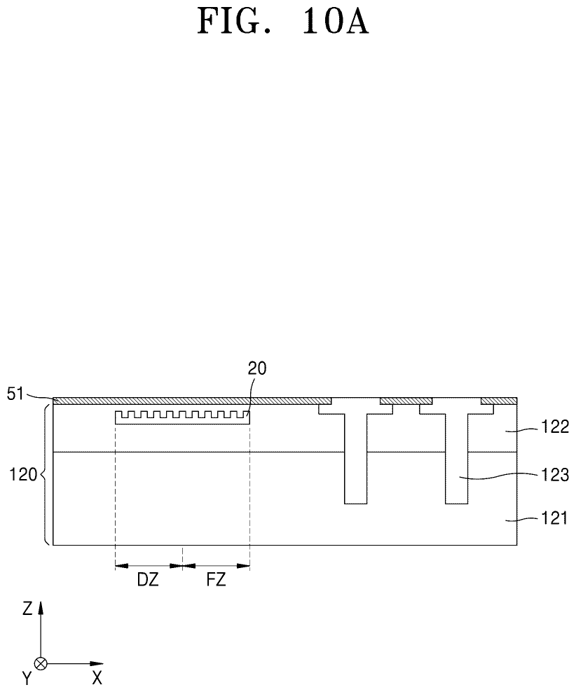

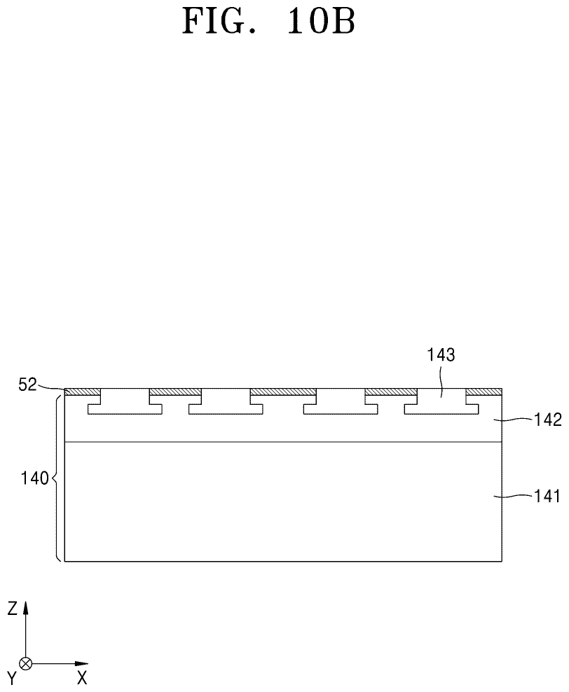

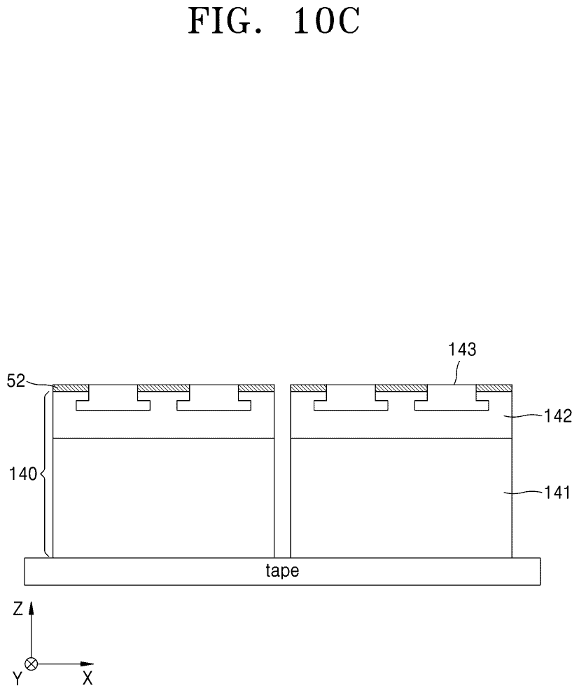

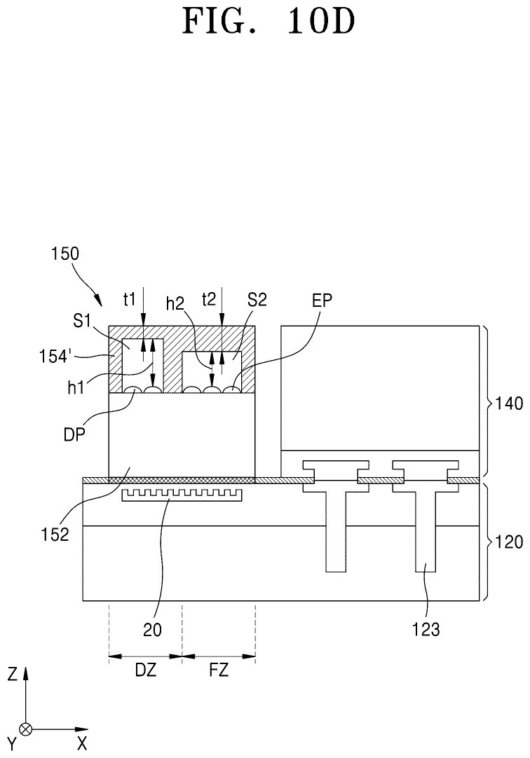

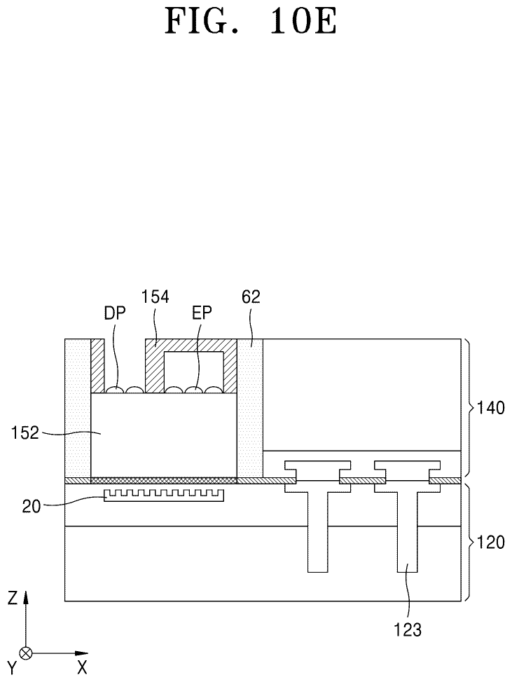

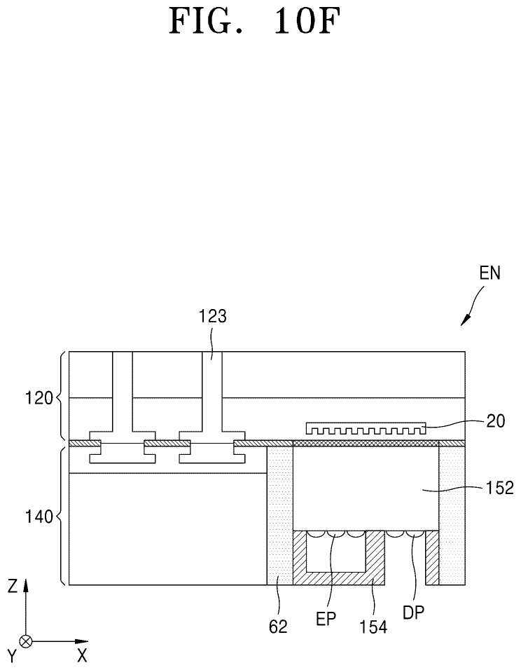

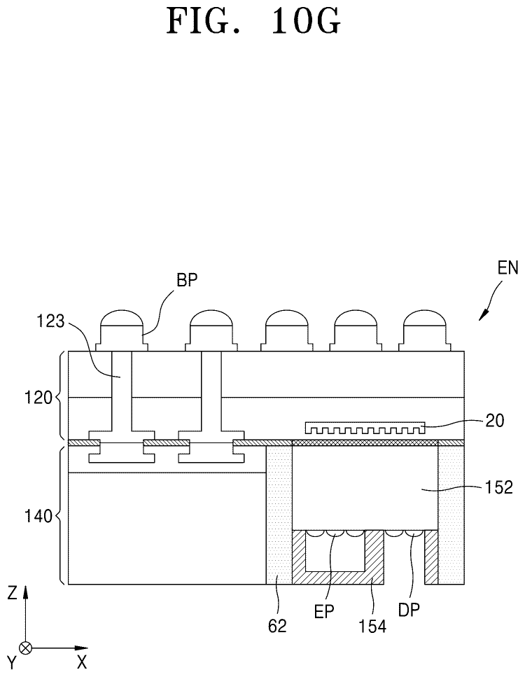

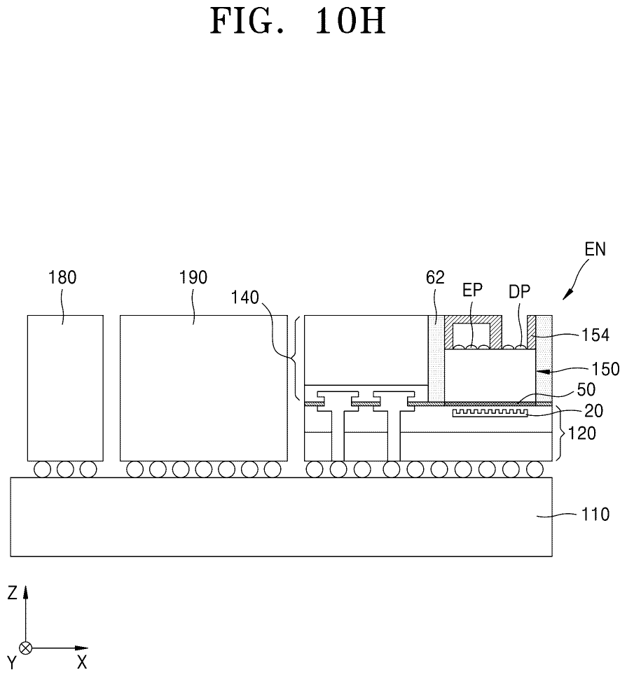

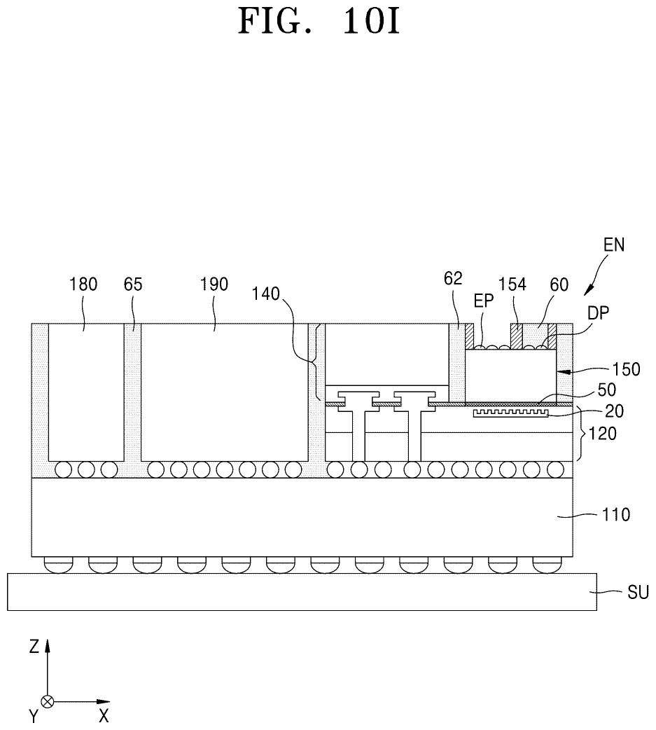

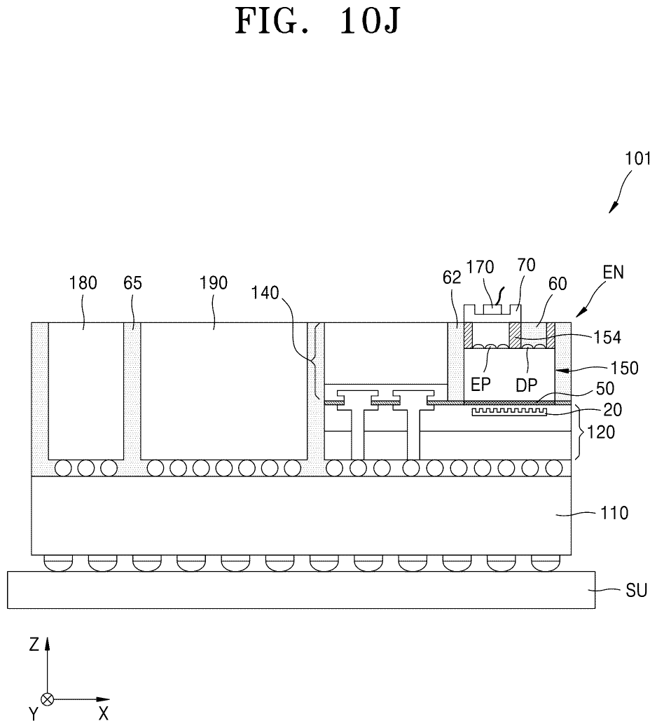

FIGS. 10A to 10J are diagrams for describing a method of manufacturing a processor package, according to an embodiment.

Referring to FIG. 10A, a PIC chip 120 may be provided. The PIC chip 120 may include a silicon layer 121 and a silicon oxide layer 122, and circuit elements for photoelectric conversion, an optical waveguide, an optical coupler, and the like may be formed in the PIC chip 120. FIG. 10A shows only some components, such as the coupling device 20 for optical path conversion and a through silicon via (TSV) electrode 123 with a top surface of the TSV electrode 123 exposed for electrical connection with an EIC 140 (see FIG. 10B), and the PIC chip 120 is not limited to the illustrated form.

The PIC chip 120 may define at least a part of a dummy channel region DZ and a function channel region FZ. As described above, the dummy channel region DZ may be a region corresponding to a dummy pattern to be formed on the PIC chip 120, and may be provided for optical testing during the manufacturing process, and the illustrated region division is a non-limiting example.

An adhesive layer 51 may be formed on the top surface of the PIC chip 120. The adhesive layer 51 may include, for example, SiCN.

Referring to FIG. 10B, an EIC chip 140 may be provided. The EIC chip 140 may include a silicon layer 141 and a silicon oxide layer 142, and may include circuit elements for driving the photonic integrated circuit. The diagram shows only some components, such as wiring 143 with a top surface of the wiring 143 exposed for electrical connection with the PIC chip 120, and the EIC chip 140 is not limited to the illustrated form. An adhesive layer 52 may be formed on the top surface of the EIC chip 140. The adhesive layer 52 may include, for example, SiCN.

Referring to FIG. 10C, the wafer-level electronic integrated circuit chip (e.g., the EIC chip 140) shown in FIG. 10B may be divided into predetermined units so as to be transferred to a particular position.

Referring to FIG. 10D, a coupling structure 150 and the EIC chip 140 may be bonded to the PIC chip 120, on the PIC chip 120.

The coupling structure 150 may be arranged at a position facing the coupling device 20 of the PIC chip 120. The coupling structure 150 may include a light-transmitting block 152, and a plurality of light output patterns and a frame 154′ formed on the top surface of the light-transmitting block 152.

The light output pattern may include an effective pattern EP and a dummy pattern DP. The effective pattern EP and the dummy pattern DP may be provided to correspond to the effective channel region FZ and the dummy channel region DZ, respectively. For example, the effective pattern EP may be in the effective channel region FZ, and the dummy pattern DP may be in the dummy channel region DZ.

The frame 154′ may have a shape surrounding the effective pattern EP and the dummy pattern DP by distinguishing (e.g., separating) the effective pattern EP from the dummy pattern DP. The frame 154′ may have a shape forming a first space S1 surrounding the dummy pattern DP and a second space S2 surrounding the effective pattern EP. A height h1 of the first space S1 may be greater than a height h2 of the second space S2. To this end, a thickness t1 of the frame 154′ at a position facing (e.g., overlapping with) the dummy pattern DP may be less than a thickness t2 of the frame 154′ at a position facing (e.g., overlapping with) the effective pattern EP. However, this is only an example, and the thickness of the frame 154′ or the shape of the top surface of the frame 154′ may be variously modified so that the height h1 of the first space S1 is greater than the height h2 of the second space S2.

Referring to FIGS. 10D and 10E together, after the region on the PIC chip 120 is molded with a mold material 62, the frame 154′ may be etched so that the upper portion of the dummy pattern DP is exposed and the upper portion of the effective pattern EP is not exposed.

The frame 154 may surround the side portion of the dummy pattern DP, expose the upper portion of the dummy pattern DP, and surround the upper portion and the side portion of the effective pattern EP.

An optical performance test using the open dummy pattern DP may be performed as described above. Optical tests may be performed only on some chips. Depending on the test results, for example, what is determined to be defective may be discarded without proceeding to the next process.

Referring to FIG. 10F, one surface of the PIC chip 120 may be etched to expose the TSV electrode 123.

Referring to FIG. 10G, at least one micro-bump BP may be formed on the optical engine EN. The at least one micro-bump BP may be formed on a surface (e.g., the surface of the PIC chip 120) where the TSV electrode 123 is exposed.

Referring to FIG. 10H, a memory 180, a processor 190, and the optical engine EN may be arranged on the interposer 110. The memory 180, the processor 190, and the optical engine EN may be electrically connected through the interposer 110.

Referring to FIG. 10I, a mold layer 60 covering the dummy pattern DP may be formed, and after the regions between the memory 180, the processor 190, and the optical engine EN are also filled with the mold material 65, the upper portion of the frame 154 may be etched to expose the effective pattern EP. The mold material 65 and the mold layer 60 may include the same material as each other, and may be provided in the same molding process. However, embodiments of the disclosure are not limited thereto. The mold material 65 and the mold layer 60 may include the same material as the mold material 62, but embodiments of the disclosure are not limited thereto.

The interposer 110, in which the memory 180, the processor 190, and the optical engine EN are packaged and integrated, may be arranged on the substrate SU. In this process, for electrical connection with the substrate SU, a process of exposing the TSV electrode formed in the interposer 110 may be performed.

Referring to FIG. 10J, a fiber array unit 170 may be arranged to face (e.g., overlap with) the effective pattern EP. A receptacle 70 may be arranged on the frame 154, and the fiber array unit 170 may be arranged within the receptacle 70.

Although the processor package 101 of FIG. 4 is illustrated to be manufactured in FIG. 10J, embodiments of the disclosure are not limited thereto. The processor package 102 of FIG. 5, the processor package 103 of FIG. 6, and the processor package 104 of FIG. 7 may be manufactured using the manufacturing method described above.

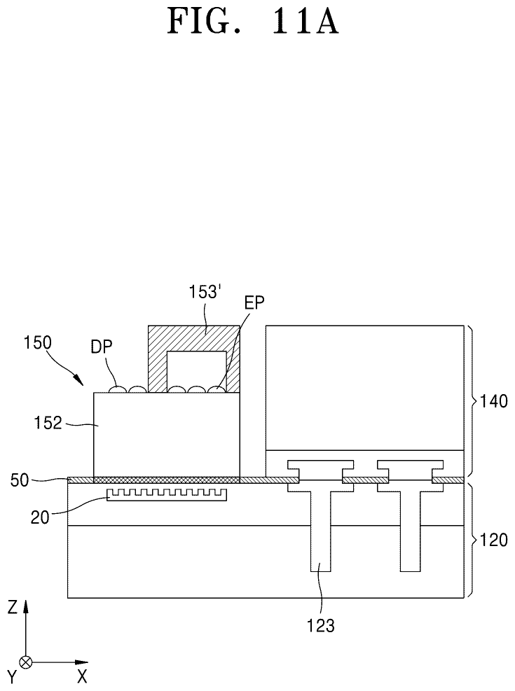

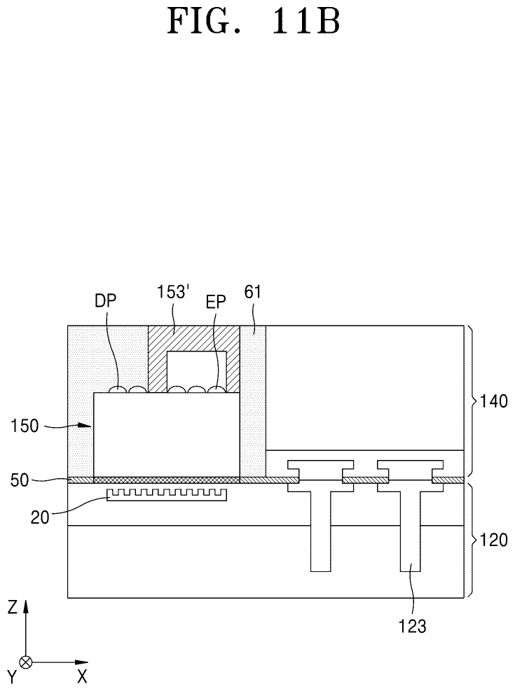

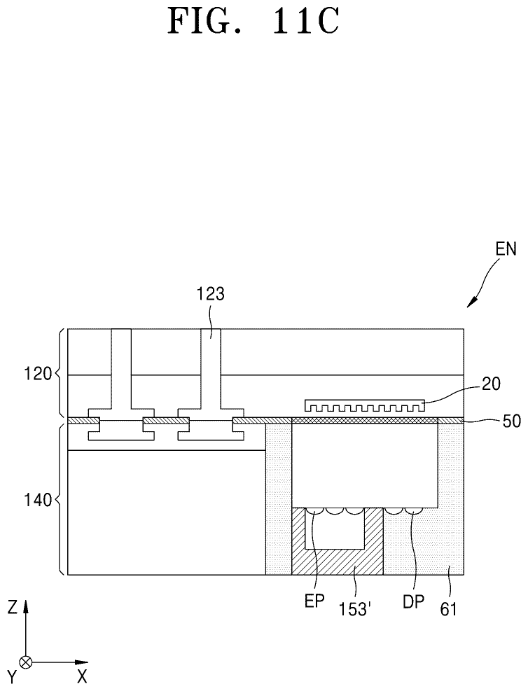

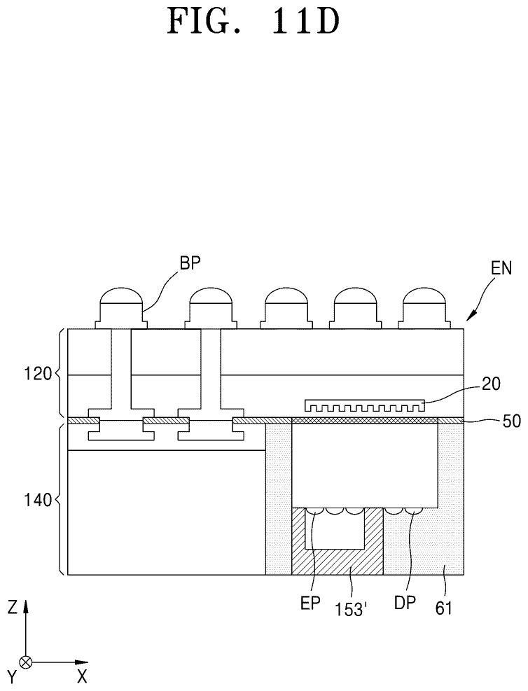

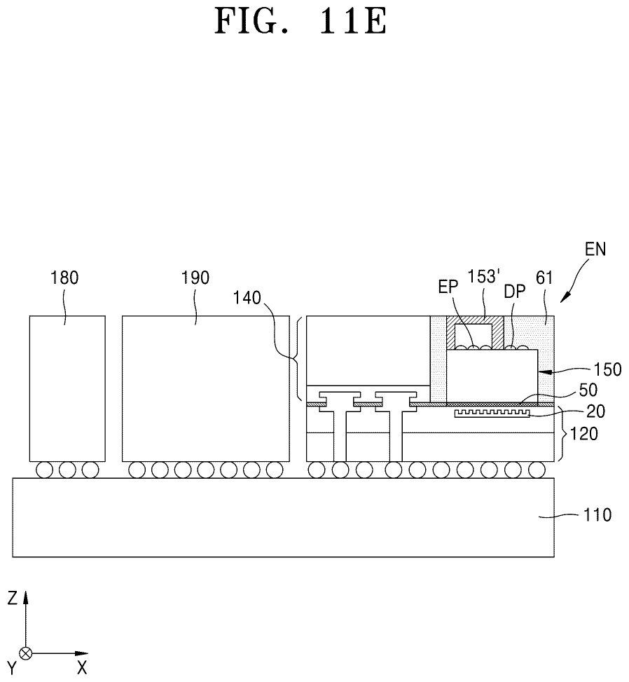

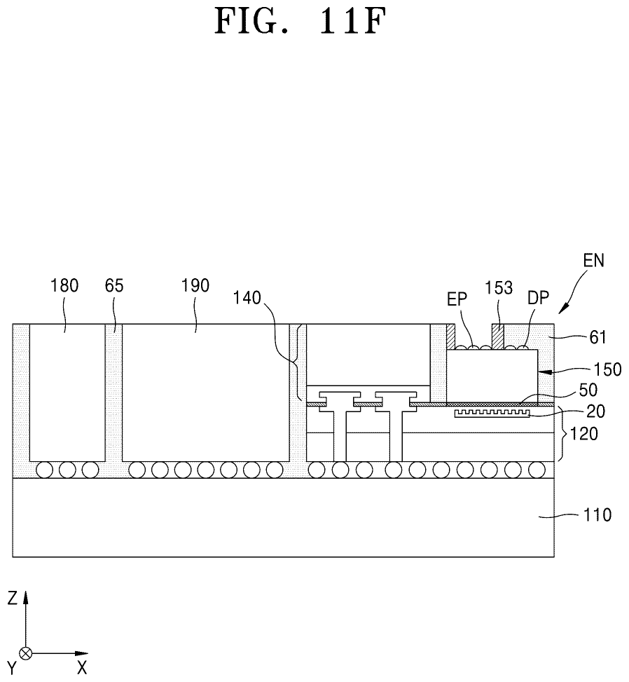

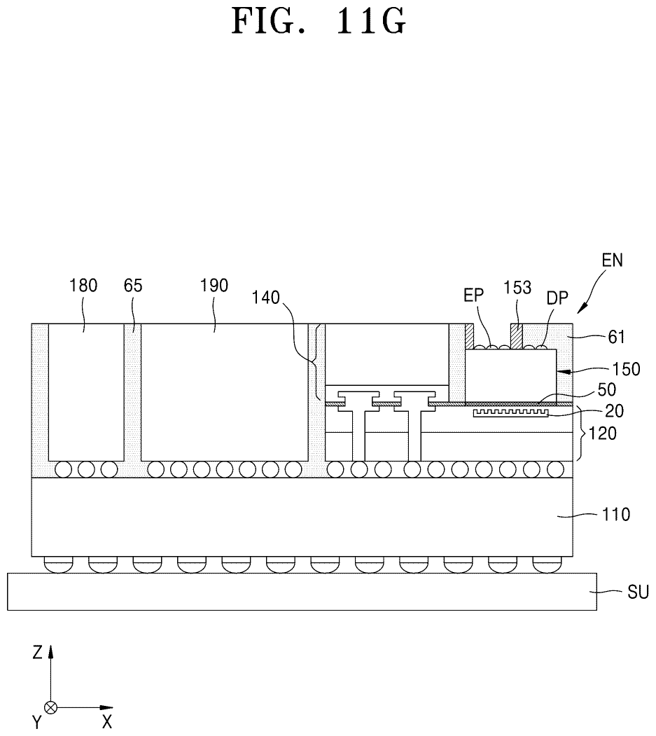

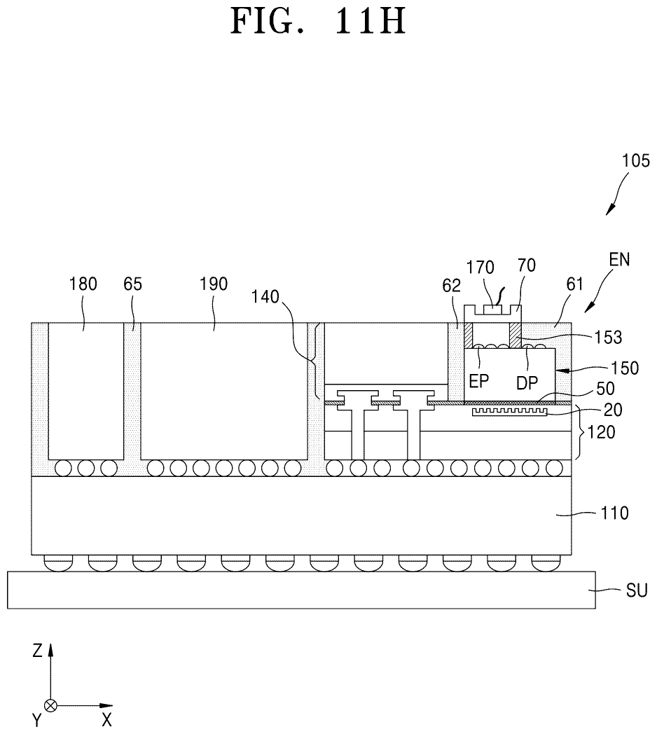

FIGS. 11A to 11H are diagrams for describing a method of manufacturing a processor package, according to an embodiment.

After the operations of FIGS. 10A to 10C, as illustrated in FIG. 11A, the coupling structure 150 and the EIC chip 140 may be bonded to each other on the PIC chip 120.

Referring to FIG. 11A, unlike FIG. 10D, the frame 153′ may have a shape surrounding only the effective pattern EP.

In this operation, an optical performance test using the open dummy pattern DP may be performed. Optical tests may be performed only on some chips. Depending on the test results, for example, what is determined to be defective may be discarded without proceeding to the next process.

Referring to FIG. 11B, a mold layer 61 covering the dummy pattern DP may be formed. The mold layer 61 may not only cover the dummy pattern DP, but may also cover the remaining regions on the PIC chip 120, such as a region between the coupling structure 150 and the EIC chip 140.

Referring to FIG. 11C, one surface of the PIC chip 120 may be etched to expose the TSV electrode 123.

Referring to FIG. 11D, at least one micro-bump BP may be formed on the optical engine EN. The at least one micro-bump BP may be formed on a surface (e.g., the surface of the PIC chip 120) where the TSV electrode 123 is exposed.

Referring to FIG. 11E, a memory 180, a processor 190, and the optical engine EN may be arranged on the interposer 110. The memory 180, the processor 190, and the optical engine EN may be electrically connected through the interposer 110.

Referring to FIGS. 11E and 11F together, after the regions between the memory 180, the processor 190, and the optical engine EN are filled with the mold material 65, the upper portion of the frame 153′ may be etched to expose the effective pattern EP. The mold material 65 may include the same material as the material of the mold layer 61, but is not limited thereto.

Referring to FIG. 11G, the interposer 110, in which the memory 180, the processor 190, and the optical engine EN are integrated, may be arranged on the substrate SU. In this process, for electrical connection with the substrate SU, a process of exposing the TSV electrode formed in the interposer 110 may be performed.

Referring to FIG. 11H, a receptacle 70 may be arranged on the frame 153, and a fiber array unit 170 may be arranged within the receptacle 70.

Although the processor package of FIG. 8 is illustrated to be manufactured in FIG. 11H, embodiments of the disclosure are not limited thereto, and the processor package 106 of FIG. 9 may be manufactured using the manufacturing method described above.

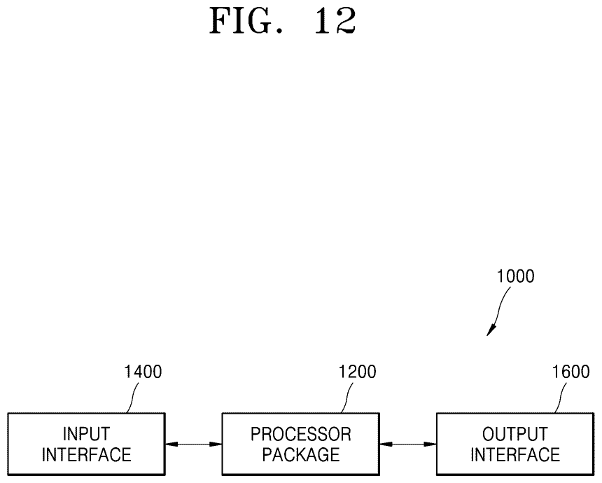

FIG. 12 is a block diagram schematically illustrating an electronic device according to an embodiment.

An electronic device 1000 may include a processor package 1200, an input interface 1400, and an output interface 1600. The input interface 1400 and the output interface 1600 may be electrically connected to the processor package 1200. The processor package 1200 may include any one of the processor packages 100 to 106 described above, or a processor package having a modified or combined structure thereof.

The processor package, manufacturing method thereof, and electronic device have been described with reference to embodiments shown in the drawings.

In the processor packages of embodiments of the disclosure, since an optical engine is packaged together with a processor on an interposer, data transmission loss may be reduced.

The optical engine provided in the processor packages of embodiments of the disclosure may have a structure that enables easy performance of an optical test in a manufacturing step, and may easily increase the number of test samples, thereby improving the yield of the finished product in a cost-effective manner.

According to a method of manufacturing a processor package of embodiments of the disclosure, a processor package having a structure with low data transmission loss may be manufactured with good yield.

Example embodiments described herein should be considered in a descriptive sense only and not for purposes of limitation. Descriptions of features or aspects of each example embodiment of the disclosure should typically be considered as available for other similar features or aspects of other embodiments of the disclosure. While one or more non-limiting example embodiments of the disclosure have been described with reference to the figures, it will be understood by those of ordinary skill in the art that various changes in form and details may be made therein without departing from the spirit and scope of the disclosure.

What is claimed is:

1. A processor package comprising:
an interposer;
a memory on the interposer;
a processor on the interposer; and
an optical engine on the interposer,
wherein the optical engine comprises:
a photonic integrated circuit chip comprising circuit elements configured to perform photoelectric conversion, and
a coupling structure on the photonic integrated circuit chip, the coupling structure configured to provide at least one of an optical input path or an optical output path, wherein the at least one of the optical input path or the optical output path is connected to the photonic integrated circuit chip,
wherein the coupling structure comprises:
a plurality of light output patterns comprising a dummy pattern and an effective pattern, and
a mold layer on the dummy pattern, and
wherein the effective pattern is configured to receive light from an outside of the optical engine.

2. The processor package of claim 1, wherein the optical engine further comprises an electronic integrated circuit chip on the photonic integrated circuit chip, the electronic integrated circuit chip configured to drive the circuit elements.

3. The processor package of claim 1, wherein the coupling structure further comprises a light-transmitting block on the photonic integrated circuit chip, wherein the plurality of light output patterns are on one surface of the light-transmitting block.

4. The processor package of claim 3, wherein the coupling structure further comprises a frame on the light-transmitting block, wherein the frame horizontally surrounds the effective pattern, and an upper portion of the effective pattern is exposed from the frame.

5. The processor package of claim 4, wherein the frame comprises a shape that surrounds the dummy pattern and the effective pattern, wherein a portion of the shape is between the dummy pattern and the effective pattern.

6. The processor package of claim 1, further comprising a mold material on the interposer, in spaces between the memory, the processor, and the optical engine,
wherein a material of the mold material is the same as a material of the mold layer.

7. The processor package of claim 1, further comprising a fiber array unit on the coupling structure and optically connected to the effective pattern.

8. The processor package of claim 1, wherein the photonic integrated circuit chip and the coupling structure comprise:
a dummy channel region comprising the dummy pattern; and
a functional channel region comprising the effective pattern.

9. The processor package of claim 1, wherein the photonic integrated circuit chip further comprises a coupling device that is configured to change an optical path in a direction toward the plurality of light output patterns.

10. The processor package of claim 1, wherein the interposer comprises a silicon interposer or a redistribution layer (RDL) interposer.

11. An electronic device comprising:
a processor package;
an input interface configured to be electrically connected to the processor package; and
an output interface configured to be electrically connected to the processor package,
wherein the processor package comprises:
an interposer,
a memory on the interposer,
a processor on the interposer, and
an optical engine on the interposer,
wherein the optical engine comprises:
a photonic integrated circuit chip comprising circuit elements, the circuit elements configured to perform photoelectric conversion, and
a coupling structure on the photonic integrated circuit chip, the coupling structure configured to provide at least one of an optical input path or an optical output path, wherein the at least one of the optical input path or the optical output path is connected to the photonic integrated circuit chip,
wherein the coupling structure comprises:
a plurality of light output patterns comprising a dummy pattern and an effective pattern, and
a mold layer on the dummy pattern, and
wherein the effective pattern is configured to receive light from an outside of the optical engine.

12. A method of manufacturing processor package, the method comprising:
forming an optical engine by arranging, on a photonic integrated circuit chip, a coupling structure and an electronic integrated circuit chip, wherein the coupling structure includes a plurality of light output patterns including a dummy pattern and an effective pattern, and the photonic integrated circuit chip includes circuit elements, the circuit elements configured to perform photoelectric conversion, and the electronic integrated circuit chip configured to drive the circuit elements;
forming a mold layer on the dummy pattern; and
arranging the optical engine on an interposer,
wherein, after the forming the mold layer, the effective pattern is configured to receive light from an outside of the optical engine.

13. The method of claim 12, wherein the coupling structure includes:
a light-transmitting block, wherein the plurality of light output patterns are on one surface of the light-transmitting block; and
a frame on the light-transmitting block and surrounding an upper portion of the effective pattern and a periphery of the effective pattern.

14. The method of claim 13, wherein the frame includes a shape that horizontally surrounds the dummy pattern and the effective pattern, wherein a portion of the shape is between the dummy pattern and the effective pattern, and
wherein the frame includes a first space above the dummy pattern and a second space above the effective pattern, wherein a height of the first space is greater than a height of the second space.

15. The method of claim 14, further comprising etching, before the forming the mold layer, an upper portion of the frame so that the dummy pattern is exposed from the frame and the effective pattern is not exposed from the frame.

16. The method of claim 13, wherein the frame includes an upper portion that is above the upper portion of the effective pattern, with a space between the upper portion of the frame and the upper portion of the effective pattern, and the dummy pattern is exposed from the frame.

17. The method of claim 16, wherein the forming the mold layer on the dummy pattern comprises providing a mold material in a region between the electronic integrated circuit chip and the coupling structure, wherein the mold material is the same as a material of the mold layer.

18. The method of claim 13, further comprising exposing, after the forming the mold layer, the effective pattern by etching the upper portion of the frame.

19. The method of claim 18, further comprising arranging a fiber array unit on the frame, the fiber array unit configured to optically connect the effective pattern.

20. The method of claim 12, wherein the interposer is a silicon interposer or a redistribution layer (RDL) interposer.
